(19) United States
(12) Patent Application Publication
(10) Pub. No.: US 2009/0166878 A1
(43) Pub. Date: Jul. 2, 2009

(54) Semiconductor Device and Method of Fabricating the Same

(76) Inventor: Jang Hyeon SEOK, Icheon-si (KR)

Correspondence Address: THE LAW OFFICES OF ANDREW D. FORTNEY, PH.D., P.C., 401 W FALLBROOK AVE STE 204, FRESNO, CA, 93711-5835, US

(21) Appl. No.: 12/338,410

(22) Filed: Dec. 18, 2008

(30) Foreign Application Priority Data
Dec. 26, 2007 (KR) 10-2007-0137275

(51) Int. Cl. H01L 23/48; H01L 21/30

(52) U.S. Cl. 257/773; 438/672; 257/E23.01; 257/E21.211

(57) ABSTRACT

Disclosed are a semiconductor device and a method of fabricating the same. The semiconductor device includes an interlayer dielectric film on a substrate, a plug in the interlayer dielectric film, a metal layer on the plug, and an impure anti-reflective coating (ARC) layer on the metal layer.

The present application claims priority under 35 U.S.C. 119 to Korean Patent Application No. 10-2007-0137275 (filed on Dec. 26, 2007), which is hereby incorporated by reference in its entirety.

### BACKGROUND

Embodiments of the present invention relate to a semiconductor device and a method of fabricating the same.

In a semiconductor device, a metallization process is performed by a via plug process and a metal line process. In addition, an anti-reflective coating (ARC) layer may be formed on the metal line.

Meanwhile, after the metallization process is performed, a sintering process based on a heat treatment may be performed in order to improve the performance of the semiconductor device.

However, in conventional manufacturing processes, thermal stress may result from the sintering process, and the difference between thermal expansion coefficients of the metal line and an inter-layer dielectric film may result in defects or problems. For example, metal lifting and inter metal dielectric (IMD) cracks may become more severe due to an interfacial reaction of the metal line and the anti-reflective coating layer. Accordingly, a pad hole phenomenon may occur, which separates the metal layer from a predetermined region (a via array region) of a metal pad. This may result in defects to an outer portion of the device and may degrade the reliability of the device.

In addition, during conventional processes, metal voids may be created between the metal line and the anti-reflective coating layer due to thermal stress.

### SUMMARY

Embodiments of the present invention provide a semiconductor device and methods of fabricating the same. The devices and methods described herein are capable of minimizing or preventing problems associated with thermal stress, by improving the characteristics of an interfacial surface between an interlayer dielectric film and a metal line.

Embodiments of the present invention also provide a semiconductor device and a method of fabricating the same, capable of preventing metal voids from being created due to thermal stress when performing a sintering process by improving the characteristic(s) of an interfacial surface between an interlayer dielectric film and a metal line.

According to embodiments of the present invention, a semiconductor device includes an inter-layer dielectric film on a substrate, a plug in the inter-layer dielectric film, a metal layer on the plug, and an impure anti-reflective coating (ARC) layer on the metal layer.

According to other embodiments of the present invention, a method of fabricating a semiconductor device includes the steps of forming an interlayer dielectric film on a substrate, forming a plug in the interlayer dielectric film, forming a metal layer on the plug, forming an impure anti-reflective coating (ARC) layer on the metal layer, forming a metal line by selectively etching the metal layer and the impure ARC layer, and sintering the metal line.

In the present semiconductor device and the method of fabricating the same a, the characteristics of an interfacial surface between the inter-layer dielectric film and the metal line may be improved by using a plasma enhanced un-doped silicate glass (PE USG) process, which enhances the characteristics of a dielectric film-metal film interface in terms of tensile stress. Accordingly, stress variation before/after the sintering process can be minimized, and a pad hole effect of a semiconductor device (e.g., a CMOS image sensor (CIS)) caused by metal lifting and IMD cracks can be effectively reduced or prevented. In addition, according to the embodiments of the present invention, defects in an outer portion of a product caused by the pad hole effect can be prevented so that the reliability of the product can be improved.

In addition, when the metal line is formed, the impure ARC layer is formed by an in-situ process, so that thermal stress variation according to the sintering process can be minimized. Accordingly, metal voids of an image sensor can be effectively prevented. In addition, the stress migration (SM) characteristics may be improved. Thus, margins of the metallization process can be ensured and the reliability of the semiconductor device (e.g., a CMOS image sensor) can be improved.

### BRIEF DESCRIPTION OF THE DRAWINGS

FIG. 1 is a cross-sectional view showing an exemplary metal line of a semiconductor device according to embodiments of the present invention; and

FIGS. 2 and 3 are graphs showing stress variation resulting from heat treatment at various temperatures for an exemplary metal line of a semiconductor device according to an embodiment of the present invention.

### DETAILED DESCRIPTION OF THE EMBODIMENTS

Hereinafter, a semiconductor device and a method of fabricating the same according to embodiments of the present invention will be described in detail with reference to accompanying drawings.

In the following description of the various embodiments, it will be understood that when a layer (or film) is referred to as being “on” or “under” another layer, it can be directly on or under the other layer, or one or more intervening layers may also be present.

Furthermore, the present invention is not limited to an image sensor, but applicable to all semiconductor devices using an anti-reflective coating (ARC) layer and a sintering process.

### EMBODIMENTS

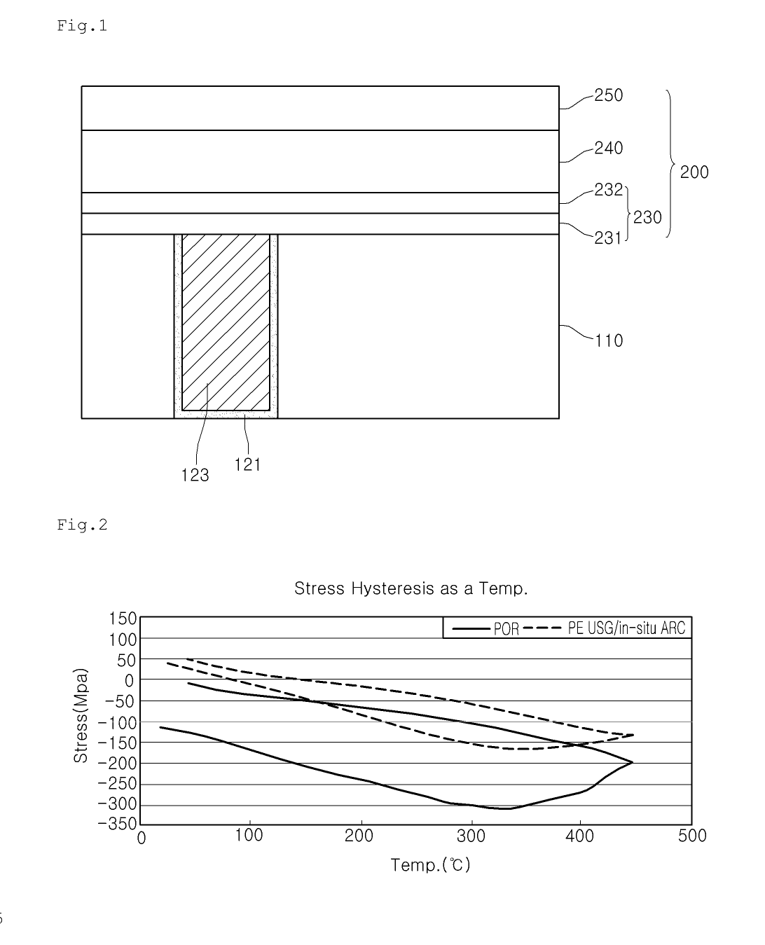

FIG. 1 is a cross-sectional view showing an exemplary metal line of a semiconductor device according to embodiments of the present invention.

In general, the semiconductor device may include an interlayer dielectric film 110 formed on a substrate (not shown), a plug 123 formed in the inter-layer dielectric film 110, a metal layer 240 formed on the plug 123, and an impure anti-reflective coating (ARC) layer 250 formed on the metal layer 240.

In preferred embodiments, the interlayer dielectric film 110 may be formed by using plasma enhanced undoped silicate glass (PE USG), but is not limited thereto. In other embodiments, the interlayer dielectric layer may include silicon nitride, silicon-rich oxide (SRO), TEOS (e.g., a silicon oxide formed by CVD from tetraethylorthosilicate and oxygen), a bulk dielectric (e.g., one or more silicon oxide layers doped with fluorine or boron and/or phosphorous [FSG, BSG, PSG, and/or BPSG]), silicon dioxide, or a combination thereof. In other variations, the interlayer dielectric film may include pre-metal dielectric (PMD) or an intermetal dielectric (IMD).

Furthermore, in some embodiments, a diffusion barrier layer 121 may be formed in the via hole, on surfaces of and the inter-layer dielectric film 110 and the underlying metal, before forming the plug 123. In some embodiments, the diffusion barrier layer 121 may comprise Ti, TiN, WN, TiW alloy, or a combination thereof, such as a TiN-on-Ti bilayer or a TiW-on-Ti-bilayer.

The impure ARC layer 250 may be an impure TiNx layer, where x<1 in preferred embodiments. In other embodiments, the impure ARC layer 250 may be a layer including Ti and TiN. In some variations, the impure ARC layer may include Ti-rich TiN or non-stoichiometric TiN (e.g., TiₓN_{y}, where x:y is from 1.1:1 to 1.5:1 or from 1.1:1 to 2:1, or any range of values therebetween). The impure ARC layer 250 may have a thickness in the range of 300 Å to 375 Å, but is not limited thereto.

Referring still to FIG. 1, in some embodiments, the metal line 200 may further include a liner layer 230 formed below the metal layer 240. The metal layer 240 may include aluminum or an alloy thereof with copper, titanium, silicon, etc., or any other suitable metal known in the art. In an alternate embodiment, the metal layer 240 may comprise copper damascene or dual damascene metal. Furthermore, the liner layer 230 may include a first liner layer 231 and a second liner layer 232. In some embodiments, the first liner layer 131 may comprise Ti or Ta and the second liner layer 232 may comprise TiN, TaN, or TiW.

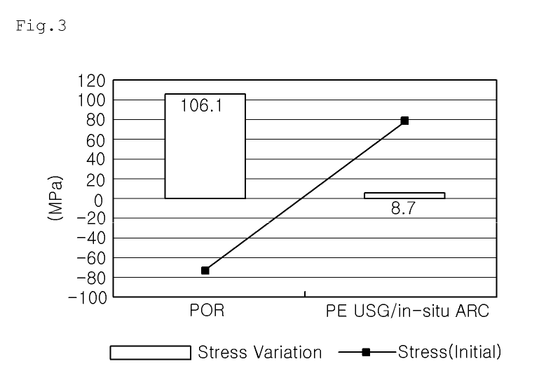

FIGS. 2 and 3 are graphs showing stress variation according to various heat/temperature treatments for the present metal line.

Specifically, FIG. 2 is a graph showing the variation of thermal stress resulting from heating a device having the metal line(s) thereon at various temperatures. In the related art (the “POR” graph), the thermal stress rapidly varies greatly according to the temperature.

In contrast, the semiconductor device according to embodiments of the present invention (“PE-USG/in-situ ARC”) has a tensile stress characteristic between the inter-layer dielectric film 110 and the metal line 200 as shown in FIG. 2. In addition, stress variation before/after heat treatment (e.g., a 450° C. sintering process) is smaller than that of a conventional IMD/Metal, so that an influence caused by thermal budge can be minimized. This reduction in interfacial stress is believed to be due to the PE USG/in-situ ARC process that is used to manufacture the metal line.

According to embodiments of the present invention, the PE USG/in-situ ARC process (I) provides sufficient and/or additional margin against thermal stress, so that it is possible to effectively reduce or prevent a pad hole effect caused by metal lifting and IMD cracking due to the 450° C. sintering process.

As shown in FIG. 3, a very rapid stress variation of about 106 MPa occurs due to the sintering process in the related art. In contrast, in the present invention, a tensile stress characteristic of about 8.7 MPa is shown due to the PE USG/in-situ ARC process (I).

In other words, in the semiconductor device according to embodiments of the present invention, the inter-layer dielectric film 110 is formed using PE-USG, and the impure ARC layer 250 is deposited on the metal layer 240 through the in-situ process, so that thermal stress variation caused by the sintering process can be minimized. Accordingly, the pad hole effect or metal voids of an image sensor or other semiconductor product can be effectively restricted.

Hereinafter, the method of fabricating the semiconductor device according to the present invention will be described with reference to FIG. 1.

An interlayer dielectric film 110 is formed on the substrate (not shown). In various embodiments, the inter-layer dielectric film 110 may include a pre-metal dielectric (PMD) or an intermetal dielectric (IMD).

The interlayer dielectric film 110 may include PE USG (e.g., as an uppermost or penultimate layer), but is not limited thereto. In some embodiments, the PE USG process may be performed at a temperature of about 400±40° C., but is not limited thereto.

Hereinafter, the characteristic(s) of the interlayer dielectric film 110 including PE USG will be described. As seen in conventional processing, as the interlayer dielectric film 110 becomes more compressive, or as the temperature increases, there is a greater difference from metal in thermal expansion coefficient. Furthermore, a push-down force from the metal layer 240 may increase, so that metal voids may be easily created.

Meanwhile, when compared to IMD processes employing PE CVD, an IMD process employing HDP CVD generally results in greater temperature variations of the substrate. Thus, metal lifting, metal voids, and resistivity (Rₛ) shift of the metal layer may occur due to thermal stress. In order to solve the problems, according to embodiments of the present invention, PE USG is deposited instead of more compressive HDP USG, so that metal voids can be prevented.

After depositing layer 110 and before depositing layer(s) 200, a via hole is formed by patterning and etching (e.g., using a photoresist) the interlayer dielectric film 110, and the plug 123 may be formed in the via hole. The plug 123 may be a contact plug or a via plug.

In some embodiments, a diffusion barrier 121 may be further formed by CVD or sputtering between the plug 123 and the inter-layer dielectric film 110.

Prior to formation of the via hole, a cap layer may be further formed on and the interlayer dielectric film 110 by plasma-assisted CVD using silane (SiH₄) and an oxygen source (e.g., O₂).

In various embodiments, a liner layer 230 may be further formed on the interlayer dielectric film 110 and the plug 123. The liner layer 230 may include a first liner layer 231, and a second liner layer 232 formed on the first liner layer 231. For example, the liner layer 230 may include a Ti liner layer 231 and a TiN liner layer 232, but is not limited thereto.

Thereafter, the metal layer 240 is formed on the liner layer 230. For example, the metal layer 240 may include AlCu, but is not limited thereto.

Then, the impure ARC layer 250 is formed on the metal layer 240. The step of forming the impure ARC layer 250 may include forming a first ARC layer (not shown), and forming a second ARC layer (not shown) on the first ARC layer, through an in-situ process.

For example, the first ARC layer may include a Ti layer. The second ARC layer may include a TiN layer and be formed through the in-situ process. However, the invention is not limited thereto.

Alternately, the impure ARC layer 250, may comprise an impure TiNx layer, formed by forming the TiN layer through an in-situ process after the Ti layer is formed, so that TiAl₃ (which may be generated through an interfacial reaction between the Ti layer and the aluminum from the AlCu layer 240) is minimized. Accordingly, metal voids caused by the sintering process can be effectively prevented.

Hereinafter, the process of forming the impure ARC layer 250 will be described in more detail.

According to exemplary embodiments, when forming the impure ARC layer 250, the first ARC layer may have a thickness of 20% to 50% of the thickness of the second ARC layer.

For example, the total thickness of both layers of the impure ARC layer 250 may be in the range of about 300 Å to 375 Å. As the thickness of the impure ARC layer 250 increases, volume shrinkage of the metal line caused by TiAl₃ is effectively prevented so that the surface morphology and the Rs drift characteristic can be improved. In other words, the electromigration (EM) and/or stress migration (SM) characteristics of metal can be improved.

However, since a hydrogen (H) trap is increased by Ti, a dark characteristic of metal layer 240 and/or impure ARC layer 250 may be degraded. Accordingly, the first ARC layer (e.g., the Ti layer) may have a thickness of 50 Å to 125 Å. In addition, when the thickness of the TiN layer is about 250 Å, margins can be sufficiently ensured in a photolithography process.

In exemplary embodiments, the impure ARC layer 250 may be formed using a power ranging from about 5 kW to about 10 kw.

Furthermore, a deposition rate (D/R) of the first ARC layer may be higher than the D/R of the second ARC layer. For example, the D/R of the ARC Ti layer may be increased (e.g., to at least 1000 Å/min or any greater minimum value, such as at least 2000, 4000, or 6000 Å/min) to minimize TiAl₃. In contrast, the D/R of the TiN layer may be decreased (e.g., to at most 2000 Å/min or any smaller maximum value, such as at most 1500, 1000, or 500 Å/min) to form a dense film. This may prevent attack on the aluminum (Al) by a developer used in the photolithography process.

The process of forming the impure ARC layer 250 may be performed at a temperature of about 50° C. or less. In other words, the Ti layer and the TiN layer may be deposited at a temperature of 50° C. or less.

In some instances, the metal line may be shortened due to Cu segregation (θ phase formation) caused by long-term holding in a chamber (e.g., at 200° C.) when a problem occurs. Accordingly, yield loss may occur. Thus, in order to prevent the above problem, it is preferable to perform the in-situ ARC process for forming the impure ARC layer at a low temperature of 50° C. or less.

In some embodiments, the first ARC layer may be formed in an atmosphere of argon (Ar) gas applied at a flow rate of 60 sccm to 100 sccm, and the second ARC layer may be formed in an atmosphere of Ar gas applied at a flow rate 40 sccm to 60 sccm and nitrogen (N₂) gas applied at a flow rate of 80 sccm to 120 sccm.

For example, in one exemplary embodiment, in order to form a dense impure TiNx film structure, the in-situ ARC process may employ a process gas of 80 sccm of Ar (e.g., during Ti deposition) and 50/100 sccm of Ar/N₂, respectively (e.g., during TiN deposition). This is desired to prevent Al attack by a developer in the photolithography process that follows.

Thereafter, the metal layer 240 and the impure ARC layer 250 are selectively etched to form the metal line 200.

Subsequently, a sintering process is performed with respect to the substrate of the metal line 200.

In the semiconductor device and the method of fabricating the same according to the various embodiments described herein, the characteristic of an interfacial surface between the inter-layer dielectric film and the metal line may be improved by the PE USG process due to the enhanced characteristics of an IMD/metal film in terms of tensile stress. Accordingly, stress variation before/after the sintering process can be minimized, and a pad hole effect of a semiconductor device (e.g., a CMOS image sensor (CIS)) caused by metal lifting and IMD cracks can be effectively restricted. In addition, according to the embodiments of the present invention, defects in and damage to an outer portion of a product caused by the pad hole effect can be prevented so that the reliability of the product may be improved.

In addition, according to exemplary embodiments described herein, when the metal line is formed, the impure ARC layer may be formed through the in-situ process so that thermal stress variation caused by the sintering process can be minimized. Accordingly, metal voids of an image sensor can be effectively prevented. In addition, since the SM characteristic is improved, margins of the metallization process can be ensured, and the reliability of the image sensor can be improved.

The present invention should not be limited to these exemplary embodiments but various changes and modifications can be made by one of ordinary skill in the art within the spirit and scope of the present invention as hereinafter claimed.

Any reference in this specification to “one embodiment,” “an embodiment,” “exemplary embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is within the purview of one skilled in the art to effect such feature, structure, or characteristic in connection with other embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
an dielectric film on a substrate;
a plug in the dielectric film;
a metal layer on the plug; and
an impure anti-reflective coating (ARC) layer on the metal layer.

2. The semiconductor device of claim 1, wherein the dielectric film includes plasma enhanced undoped silicate glass (PE USG).

3. The semiconductor device of claim 1, wherein the impure ARC layer comprises an impure TiNx layer.

4. The semiconductor device of claim 1, further comprising a diffusion barrier between the plug and the dielectric film.

5. The semiconductor device of claim 1, wherein the impure ARC layer comprises TiNx, wherein x is less than 1.

6. The semiconductor device of claim 1, wherein the impure ARC layer has a thickness of 300 Å to 375 Å.

7. The semiconductor device of claim 1, wherein the impure ARC layer comprises a first Ti ARC layer and a second TiN ARC layer.

8. The semiconductor device of claim 1, further comprising a liner layer below the metal layer.

9. The semiconductor device of claim 8, wherein the liner layer comprises a first Ti liner layer and a second TiN liner layer.

10. A method of fabricating a semiconductor device, the method comprising the steps of:
forming a dielectric film on a substrate;
forming a plug in the dielectric film;
forming a metal layer on the plug;
forming an impure anti-reflective coating (ARC) layer on the metal layer;
forming a metal line by selectively etching the metal layer and the impure ARC layer; and
sintering the metal line.

11. The method of claim 10, wherein forming the dielectric film comprises plasma enhanced CVD.

12. The method of claim 10, wherein the dielectric film comprises an un-doped silicate glass (PE USG).

13. The method of claim 10, wherein the step of forming the impure ARC layer includes the steps of:
forming a first ARC layer; and
forming, in-situ, a second ARC layer on the first ARC layer.

14. The method of claim 13, wherein the first ARC layer comprises Ti, and the second ARC layer comprises TiN.

15. The method of claim 14, wherein the impure ARC layer comprises impure TiNx.

16. The method of claim 13, wherein the first ARC layer has a thickness that is 20% to 50% of a thickness of the second ARC layer.

17. The method of claim 13, wherein a deposition rate of the first ARC layer is higher than a deposition rate of the second ARC layer.

18. The method of claim 10, wherein the impure ARC layer is formed at a temperature of 50° C. or less.

19. The method of claim 10, further comprising forming a diffusion barrier between the plug and the dielectric film.

20. The method of claim 10, further comprising forming a liner layer on the dielectric film.
